(19) United States
(12) Patent Application Publication
(10) Pub. No.: US 2025/0140615 A1
(43) Pub. Date: May 1, 2025

(54) YIELD IMPROVEMENTS IN STACKED PACKAGING

(71) Applicant: KLA Corporation, Milpitas, CA (US)

(72) Inventor: Xuewen Wang, Shanghai (CN)

(21) Appl. No.: 18/925,607

(22) Filed: Oct. 24, 2024

Related U.S. Application Data
(60) Provisional application No. 63/546,251, filed on Oct. 30, 2023.

(51) Int. Cl. H01L 21/66; G03F 7/00

(52) U.S. Cl. CPC H01L 22/12; G03F 7/70608; G03F 7/706841

(57) ABSTRACT

Shape-changed induced stress for a target thickness of a bonded wafer can be determined. A bonding strength for the bonded wafer can then be determined using the shape-changed induced stress. Bonding parameters can be determined for the bonding strength. The bonding strength that is determined can be compared with an inline bonding strength for formation of the bonded wafer.

### CROSS-REFERENCE TO RELATED APPLICATIONS

This application claims priority to the provisional patent application filed Oct. 30, 2023 and assigned U.S. App. No. 63/546,251, the disclosure of which is hereby incorporated by reference.

### FIELD OF THE DISCLOSURE

This disclosure relates to metrology of bonded wafers.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Bonded (or stacked) wafers are frequently used in the semiconductor industry. One or more ultrathin wafers bonded to a carrier wafer is an example of a bonded wafer, though other semiconductor wafer designs also can be bonded wafers. For example, a bonded wafer can include a top wafer (e.g., a device wafer) bonded to a carrier wafer. These bonded wafers can be used for both memory and logic applications. Three-dimensional integrated circuits (3D IC) can be produced using bonded wafers.

Fabrication errors in bonded wafers can cause problems during manufacturing. For example, centricity of the bonded wafer affects the CMP process or increases handling risks. During CMP, centricity affects placement of the polishing pad with respect to the center of the bonded wafer and subsequent planarization. During wafer handling, the balance of a bonded wafer or clearance within manufacturing equipment can be affected by centricity of the bonded wafer.

Improper centricity can even ruin a bonded wafer or damage manufacturing equipment. If the bonded wafer is undercut, improperly bonded together, or contains too much glue, then the bonded wafer can break within the CMP tool, contaminating or damaging the CMP tool. Such contamination or damage leads to unwanted downtime or can even stop production within a semiconductor fab.

Shape-induced stress change occurs during the packaging process. Thinning or other grinding processes can influence a shape change, which may lead to a bonding failure. Evidence shows if a top wafer is thinned down, the shape of bonded stacks tends to resemble that of the bottom wafers because of the gradual release of mechanical strength related to top wafer. Unaddressed shape changes can lead to bonding interface stress, especially in copper/dielectric oxide interfaces. Bonding interface stress may induce voids or even wafer crack at the bonding interface. Also, as bonding pitch decreases, delamination is more likely to occur at a bonding interface because small pitch oxide spaces are not wide enough to release stress. von Mises stress is higher in bonding metal pad corners and tripe points (i.e., corner of the metal pad) formed by the bonding interface and metal pad walls. This may negatively impact reliability.

Thinning or other grinding processes, such as those using abrasive wheels to remove materials, are rough and may induce local crack or grinding debris enters from the edge. This can damage the resulting devices. Stress change in a post-bonding process is not taken into consideration. Thus, failure risk induced by thinning/grinding or other post-bonding processes cannot be reduced. Improved techniques and systems for measuring bonded wafers and improving these processes are needed.

### BRIEF SUMMARY OF THE DISCLOSURE

A method is provided in a first embodiment. The method includes measuring a top wafer shape for a top wafer and a bottom wafer shape for a bottom wafer. Using a processor, shape-changed induced stress for a target thickness of a bonded wafer that includes the top wafer and the bottom wafer is determined using a model. Using the processor, a bonding strength is determined using the shape-changed induced stress. Using the processor, bonding parameters are determined for the bonding strength. Using the processor, a comparison of the bonding strength with an inline bonding strength for formation of the bonded wafer is determined.

The shape-changed induced stress may be determined for an interface between copper and a dielectric oxide.

The model may be a hypermodel or a machine learning algorithm.

The inline bonding strength may be a value used in a bonder to form the bonded wafer or a value to be used in a bonder to form the bonded wafer.

The method can include bonding the top wafer and the bottom wafer to form the bonded wafer when the comparison is within a specification prior to the bonding.

The method can include thinning the top wafer of the bonded wafer; measuring a wafer shape of the bonded wafer after the thinning; and comparing the wafer shape with a simulated wafer shape for the bonded wafer. The method can further include inspecting the bonded wafer for defects at regions based on the comparing of the wafer shape with the simulated wafer shape. The method can further include using results of the inspecting as feedback for the model. The method can further include using results of the inspecting in a feedforward manner for a next manufacturing process of the bonded wafer.

The shape-changed induced stress for a target thickness may be based on one or more of a target thickness, an interface structure of the bonded wafer, materials of the bonded wafer, or parameters of a thinning process for the bonded wafer.

A system is provided in a second embodiment. The system includes a metrology tool with a light source, a stage, a detector to receive light from the light source, and a processor in electronic communication with the detector. The processor is configured to receive measurements from the detector of a top wafer shape for a top wafer and a bottom wafer shape for a bottom wafer as the top wafer and the bottom wafer are disposed on the stage; determine shape-changed induced stress for a target thickness of a bonded wafer that includes the top wafer and the bottom wafer using a model; determine a bonding strength using the shape-changed induced stress; determine bonding parameters for the bonding strength; and determine a comparison of the bonding strength with an inline bonding strength for formation of the bonded wafer.

The model may be a hypermodel or a machine learning algorithm.

A non-transitory computer-readable storage medium is provided in an embodiment. The non-transitory computer-readable storage medium includes one or more programs for executing the following steps on one or more computing devices. Measurements of a top wafer shape for a top wafer and a bottom wafer shape for a bottom wafer are received. Shape-changed induced stress for a target thickness of a bonded wafer that includes the top wafer and the bottom wafer is determined using a model. A bonding strength using the shape-changed induced stress is determined. Bonding parameters for the bonding strength are determined. A comparison of the bonding strength with an inline bonding strength for formation of the bonded wafer is determined.

The model may be a hypermodel or a machine learning algorithm.

The inline bonding strength may be a value used in a bonder to form the bonded wafer or a value to be used in a bonder to form the bonded wafer.

### DESCRIPTION OF THE DRAWINGS

For a fuller understanding of the nature and objects of the disclosure, reference should be made to the following detailed description taken in conjunction with the accompanying drawings, in which:

FIG. 1 is a flowchart of an embodiment of a method in accordance with the present disclosure;

FIG. 2 is a flowchart of an embodiment of the method of FIG. 1; and

FIG. 3 is a block diagram of an exemplary system in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

The embodiments disclosed herein relate to advanced packaging, such as hybrid bonding techniques. Bonding yield and defect inspection efficiency can be improved. Failure risk caused by wafer or die shape change during thinning or other grinding processes is reduced. In an instance, wafer shapes of a top wafer and bottom wafer are measured. A process corner of the bonding process can be determined according to a target thickness. The applied bonding recipe is checked to determine if it is within a specification of the determined process corner. The top wafer and bottom wafer can be bonded if they are within specification. A backside of the top wafer can be thinned/grinded and polished. Then the overlay and/or shape of the bonded wafer can be determined and defects in the bonded interface can be inspected. Thermal cycling results can be checked depending on the requirements.

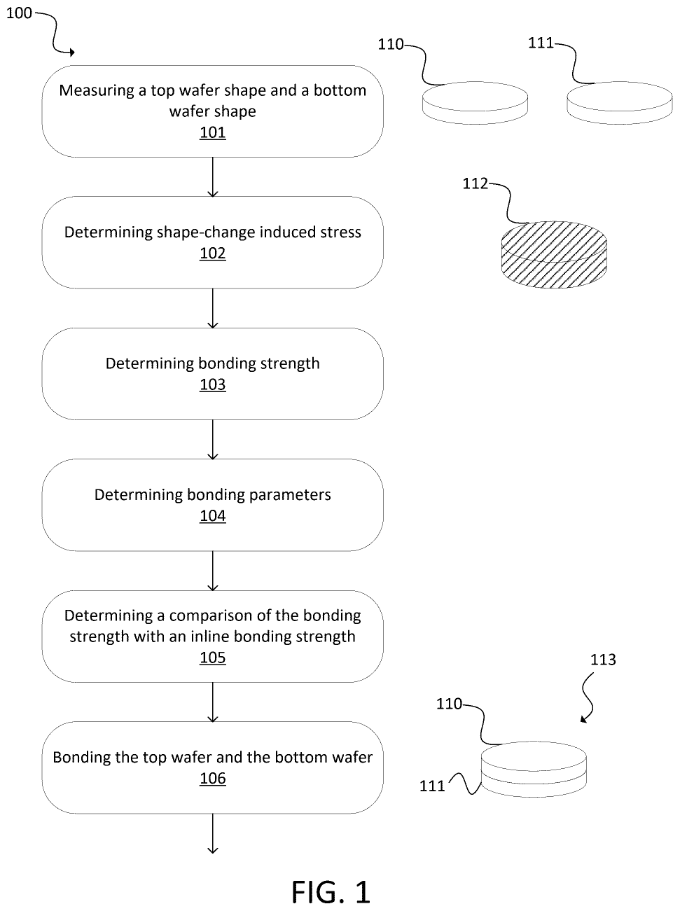

FIG. 1 is a flowchart of method 100. The method 100 can decrease failure risk caused by stress change in a post-bonding process. The method 100 may be particularly useful in decreasing failure risk caused by a thinning or other grinding process. Some of the steps of the method 100 can be performed using a processor.

At 101, a shape of a top wafer 110 and a bottom wafer 111 are measured. These measurements may be generated in one step or in two steps. For example, the top wafer 110 and the bottom wafer 111 may be measured separately. The top wafer 110 is generally the wafer subject to thinning or other grinding processes. The bottom wafer 111 may be a carrier wafer. Thus, the top wafer 110 can be assumed to be subject to thinning or grinding while the bottom wafer 111 can be assumed to remain unchanged during manufacturing.

At 102, determination of a shape-changed induced stress 113 for a target thickness of a bonded wafer that includes the top wafer 110 and the bottom wafer 111 is performed with a model. The shape-changed induced stress 113 measures, for example, bonding interface distortion, such as between the top wafer 110 and the bottom wafer 111. The model may be, for example, a hypermodel (i.e. a hyperparameter model), another physical model, a machine learning algorithm (e.g., a neural network), or a combination thereof. For example, the shape-changed induced stress can be determined for an interface between copper and a dielectric oxide, though other locations are possible. The target thickness may be a pre-set or designed thickness of the top wafer 110 after thinning/grinding or a CMP process. Thus, the target thickness may be for the bonded wafer after thinning or grinding.

In an embodiment, the hypermodel includes a physical model and specific model between the top and bottom wafer shapes and bonder parameters, such as runout setting and vacuum drop time. The coefficient of model boundary conditions can be adjusted for bonding or other aspects of the manufacturing process. In an instance, the hypermodel can perform a design of experiments (DOE) for correlation. The hypermodel can be based on historical data. In an instance, the hypermodel is used with a machine learning algorithm.

The shape-changed induced stress for a target thickness may be based on one or more of a target thickness, an interface structure of the bonded wafer, materials of the bonded wafer, or parameters of a thinning process for the bonded wafer.

Bonding strength is determined at 103 using the shape-changed induced stress. The shape-changed induced stress can include a change in stress and/or distribution. The bonding strength can be determined based on a physical equation. The bonding strength can fit the interface stress induced by a wafer shape difference. The bonding strength may be configured to avoid wafer delamination.

Bonding parameters for the bonding strength are determined at 104. The bonding parameters may be determined using a data-based model. The bonding parameters can include bonding recipe parameters for a particular bonding strength, such as bonding temperature, bonding pressure, bonding duration, vacuum drop time, runout settings, heating and/or cooling curves, or dielectric roughness. This connects the bonding strength and/or bonding energy to other bonding parameters, such as bonding temperature, bonding duration, or bonding pressure.

At 105, a comparison of the bonding strength from step 103 and an inline bonding strength for formation of the bonded wafer is determined. The inline bonding strength may be a value that was used in a bonder to form a similar bonded wafer. The inline bonding strength also may be a value to be used in a bonder to form the bonded wafer if the bonded wafer is not yet fabricated. If the bonding strength from step 103 and an inline bonding strength match, then a risk of being out-of-specification and defect type/location after a thinning and/or grinding process with inline bonding parameters can be determined, such as with a data-based model. This risk may be low if the bonding strength from step 103 and the inline bonding strength match. For example, if bonding strength is not in a suitable range, a split or void at a copper/dielectric oxide edge is more likely to happen. If the comparison does not match, then the top wafer and bottom wafer can be repaired or the bonding recipes can be evaluated. The prediction model can be based on historical data or another training model.

The top wafer 110 and the bottom wafer 111 are then bonded at 106 to form a bonded wafer 113. The bonding at step 106 may occur if the comparison from step 105 is within a specification prior to the bonding. Thus, the bonded wafer 113 may not be formed unless it passes evaluation during step 105. In an instance, a killing defect rate can be a specification used in step 106.

In another embodiment, the shape-induced stress calculation is based on multiple conditions. This may not only include target thickness after thinning, but also can include one or more of steps or parameters of thinning, designed interface structures, material properties, etc. Here, steps or parameters of thinning may include a thinning method such as a mechanical process, chemical mechanical process, thinning rate, etc. Designed interface structures may include pitch, dielectric oxide types, copper pad critical dimension, etc. Material properties may include binding energy. Note that the top wafer 110 can include a die and, thus, the thinning process may need more attention to avoid device damage.

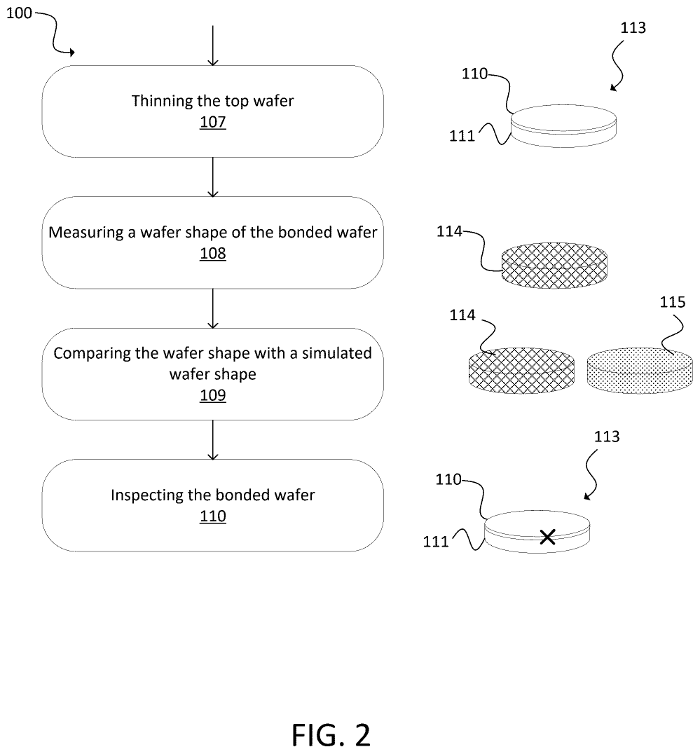

Turning to FIG. 2, after the bonded wafer 113 is formed in step 106, the top wafer 110 of the bonded wafer 113 optionally may be thinned or subject to another grinding process at 107. If the target thinning thickness for the top wafer 110 is ultra-thin (e.g., <100 nm), surface defect monitoring may be performed after the thinning. CMP or wet etch can be used to thin the top wafer 110.

A wafer shape 114 of the bonded wafer 113 can be measured at 108 after the thinning at step 107. This can be used to validate the model. The measurements also can be used to determine if inspection of high-risk areas should be performed or to determine that inspection may be skipped in certain regions because of low risk for defects. In an instance, a patterned wafer geometry metrology tool can be used to measure wafer shape 114.

The wafer shape 114 can be compared against a simulated wafer shape 115 for the bonded wafer at 109. The simulated wafer shape 115 can be calculated for an ideal or expected bonded wafer. The simulated wafer shape 115 also can be actual measurements of a bonded wafer. If the two match, one or more defect inspection parameters, including sampling, defect categories worthy of attention etc., can be determined using a previous out-of-specification prediction. Otherwise, the prediction model is unreliable and may need extra training.

At 110, the bonded wafer 113 can be inspected for defects. A metrology tool can be selected to measure the bonded wafer 113 depending on a thickness of the bonded wafer 113. These defects may be killer defects. The regions that are inspected for defects can be based on the comparison between the wafer shape 114 and the simulated wafer shape 115. The region for inspection in FIG. 2 is shown with an X on the bonded wafer 113.

Optionally, the results of the inspection at step 110 can be used as feedback for the model used in step 102. The results of the inspection at step 110 can be optionally used in a feedforward manner for the next manufacturing process for the bonded wafer 113. Thus, previous manufacturing steps can be adjusted for other bonded wafers to improve results or later manufacturing steps can be adjusted to compensate for the current bonded wafer.

In another embodiment, the top and bottom wafer shapes are measured. These measurement results are inputted into a machine learning model with the target thickness, bonding parameters, and other information. The machine learning model (e.g., a neural network) can output possible defect categories and distribution after a thinning and/or grinding process. The bonding can occur if the output is within a specification. Otherwise, the bonding parameters can be tuned. The machine learning model can be created through historical data or through the software library. The machine learning model also can add one or more physical analogs (e.g., formulas of the mechanics of materials) as limiting condition. For example, a target thickness can be designed or pre-determined after a thinning/grinding process or before a next lithography process. Bonding parameters can include inline bonding recipe parameters, such as bonding temperature, bonding period, bonding pressure, alignment model etc. Other information can include thinning and/or grinding parameters, stack material parameters etc. The method can include thinning and/or grinding the top wafer. Here, the top wafer is assumed to be wafer that will be thinned or grinded. If the thinning wafer thickness is less than 100 nm, a thinning surface becomes may influence a bonding interface. Thus, surface defects on top wafer may need a more thorough inspection. Note that a defect inspection can still be performed when wafer thickness is over 100 nm. Then, defect inspection can be based on predicted defect categories and distribution. The inspection results can be used as feedback to the machine learning model and to improve model accuracy.

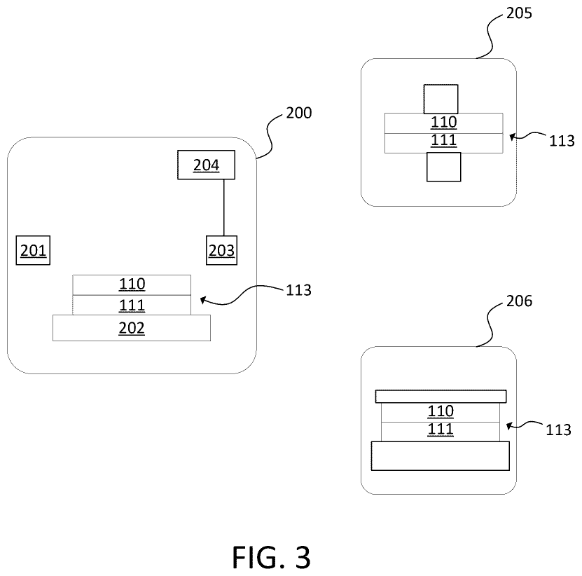

FIG. 3 is a block diagram of a system, which includes a measurement tool 200, a bonder 205, and a grinding/thinning tool 206. The measurement tool 200 can include a light source 201, a stage 202, a detector 203 to receive light from the light source 201 (e.g., light reflected off the bonded wafer 113), and a processor 204 in electronic communication with the detector 203. The measurement tool 200 can generate the measurements of the bonded wafer 113 used in the method 100 of FIGS. 1-2. The bonder 205 and grinding/thinning tool 206 can perform other steps of the method 100.

The processor 204 may include one or more processors configured to execute any of various process steps. In embodiments, the processor 204 is configured to generate and provide one or more control signals configured to perform one or more adjustments to one or more process tools based on information from the detector 203.

The processor 204 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In an embodiment, the one or more processors may be embodied as a desktop computer, mainframe computer system, workstation, image computer, parallel processor, networked computer, or any other computer system configured to execute a program configured to operate or operate in conjunction with the measurement tool 200, as described throughout the present disclosure. Moreover, different subsystems of the measurement tool 200 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single processor or, alternatively, multiple processors. Additionally, the processor 204 may include one or more processors housed in a common housing or within multiple housings. In this way, any processor or combination of processors may be separately packaged as a module suitable for integration into imaging measurement tool 200. Further, the processor 204 may analyze data received from the detector 203 and feed the data to additional components within the measurement tool 200 or external to the measurement tool 200.

The bonder 205 can be configured to bond the bonded wafer 113 using heat and/or mechanical force. The grinding/thinning tool 206 can remove material from the top wafer 110 of the bonded wafer 113. The bonder 205 and/or the grinding/thinning tool 206 can be in electronic communication with the processor 204 and/or receive instructions from the processor 204.

An additional embodiment relates to a non-transitory computer-readable medium storing program instructions executable on a processor for performing a computer-implemented method for reducing failure risk caused by wafer or die shape change during thinning or other grinding processes, as disclosed herein. An electronic data storage unit or other storage medium may contain non-transitory computer-readable medium that includes program instructions executable on the processor 204. The computer-implemented method may include any step(s) of any method(s) described herein, such as the method 100 in FIGS. 1-2.

Program instructions implementing methods such as those described herein may be stored on computer-readable medium, such as in the electronic data storage unit or other storage medium. The computer-readable medium may be a storage medium such as a magnetic or optical disk, a magnetic tape, or any other suitable non-transitory computer-readable medium known in the art. The electronic data storage unit may be housed in a common housing with the one or more processors. The electronic data storage unit also may be located remotely with respect to the physical location of the one or more processors. For instance, the one or more processors of may access a remote memory (e.g., server), accessible through a network (e.g., internet, intranet and the like).

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (MFC), Streaming SIMD Extension (SSE), or other technologies or methodologies, as desired.

Each of the steps of the method may be performed as described herein. The methods also may include any other step(s) that can be performed by the processor and/or computer subsystem(s) or system(s) described herein. The steps can be performed by one or more computer systems, which may be configured according to any of the embodiments described herein. In addition, the methods described above may be performed by any of the system embodiments described herein.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A method comprising:
measuring a top wafer shape for a top wafer and a bottom wafer shape for a bottom wafer;
determining, using a processor, shape-changed induced stress for a target thickness of a bonded wafer that includes the top wafer and the bottom wafer using a model;
determining, using the processor, a bonding strength using the shape-changed induced stress;
determining, using the processor, bonding parameters for the bonding strength; and
determining, using the processor, a comparison of the bonding strength with an inline bonding strength for formation of the bonded wafer.

2. The method of claim 1, wherein the shape-changed induced stress is determined for an interface between copper and a dielectric oxide.

3. The method of claim 1, wherein the model is a hypermodel.

4. The method of claim 1, wherein the model is a machine learning algorithm.

5. The method of claim 1, wherein the inline bonding strength is a value used in a bonder to form the bonded wafer.

6. The method of claim 1, wherein the inline bonding strength is a value to be used in a bonder to form the bonded wafer.

7. The method of claim 1, further comprising bonding the top wafer and the bottom wafer to form the bonded wafer, and wherein the comparison is within a specification prior to the bonding.

8. The method of claim 7, further comprising:
thinning the top wafer of the bonded wafer;
measuring a wafer shape of the bonded wafer after the thinning; and
comparing the wafer shape with a simulated wafer shape for the bonded wafer.

9. The method of claim 8, further comprising inspecting the bonded wafer for defects at regions based on the comparing of the wafer shape with the simulated wafer shape.

10. The method of claim 9, further comprising using results of the inspecting as feedback for the model.

11. The method of claim 9, further comprising using results of the inspecting in a feedforward manner for a next manufacturing process of the bonded wafer.

12. The method of claim 1, wherein the shape-changed induced stress for a target thickness is based on one or more of a target thickness, an interface structure of the bonded wafer, materials of the bonded wafer, or parameters of a thinning process for the bonded wafer.

13. A system comprising:
a metrology tool that includes:
a light source;
a stage;
a detector to receive light from the light source; and
a processor in electronic communication with the detector;
wherein the processor is configured to:
receive measurements from the detector of a top wafer shape for a top wafer and a bottom wafer shape for a bottom wafer as the top wafer and the bottom wafer are disposed on the stage;
determine shape-changed induced stress for a target thickness of a bonded wafer that includes the top wafer and the bottom wafer using a model;
determine a bonding strength using the shape-changed induced stress;
determine bonding parameters for the bonding strength; and
determine a comparison of the bonding strength with an inline bonding strength for formation of the bonded wafer.

14. The system of claim 13, wherein the model is a hypermodel.

15. The system of claim 13, wherein the model is a machine learning algorithm.

16. A non-transitory computer-readable storage medium, comprising one or more programs for executing the following steps on one or more computing devices:
receiving measurements of a top wafer shape for a top wafer and a bottom wafer shape for a bottom wafer;
determining shape-changed induced stress for a target thickness of a bonded wafer that includes the top wafer and the bottom wafer using a model;
determining a bonding strength using the shape-changed induced stress;
determining bonding parameters for the bonding strength; and
determining a comparison of the bonding strength with an inline bonding strength for formation of the bonded wafer.

17. The non-transitory computer-readable storage medium of claim 16, wherein the model is a hypermodel.

18. The non-transitory computer-readable storage medium of claim 16, wherein the model is a machine learning algorithm.

19. The non-transitory computer-readable storage medium of claim 16, wherein the inline bonding strength is a value used in a bonder to form the bonded wafer.

20. The non-transitory computer-readable storage medium of claim 16, wherein the inline bonding strength is a value to be used in a bonder to form the bonded wafer.
